(19) United States
(12) Patent Application Publication
(10) Pub. No.: US 2020/0270775 A1
(43) Pub. Date: Aug. 27, 2020

(54) ELECTRICALLY CONDUCTIVE YARNS AND ELECTRICALLY CONDUCTIVE FABRICS MADE THEREFROM

(71) Applicant: EXODUS INNOVATION LTD., Sufa (IL)

(72) Inventor: Isaac OPPENHEIM, Bnei Netzarim (IL)

(21) Appl. No.: 16/284,181

(22) Filed: Feb. 25, 2019

(51) Int. Cl. D02G 3/44; D02G 3/32; D04B 31/02; D02G 3/36; D03D 1/00; D04B 1/18; D04B 21/20; D04C 1/02; D03D 15/08; D04B 1/16; D04C 1/06; D02G 3/12; H05K 9/00; H01B 3/30; H01B 13/26; H01B 7/17

(52) U.S. Cl. CPC D02G 3/441; D10B 2101/20; D04B 31/02; D02G 3/36; D03D 1/00; D04B 1/18; D04B 21/20; D04C 1/02; D03D 15/08; D04B 1/16; D04C 1/06; D02G 3/12; H05K 9/0098; H01B 3/302; H01B 13/26; H01B 7/17; D10B 2331/10; D10B 2401/16; D03D 2700/0103; D03D 2700/0133; D03D 2700/0166; D02G 3/32

(57) ABSTRACT

An electrically conductive yarn including an elastomeric monofilament and an electrically conductive thread crocheted about the elastomeric monofilament. A method of forming an electrically conductive fabric including providing an elastic monofilament, enclosing the elastic monofilament with a conductive thread by crocheting, thereby producing a conductive elastic yarn and forming an electrically conductive fabric from the conductive elastic yarn and an electrically conductive fabric formed thereby.

### FIELD OF THE INVENTION

The present invention relates to electrically conductive yarns and fabrics generally and to shielded electrical conductors and to methods of manufacture thereof.

### BACKGROUND OF THE INVENTION

Various types of electrically conductive yarns and fabrics as well as shielded electrical conductors are known in the art.

### SUMMARY OF THE INVENTION

The present invention seeks to provide electrically conductive yarns and fabrics and methods for the manufacture thereof

There is thus provided in accordance with a preferred embodiment of the present invention an electrically conductive yarn including an elastomeric monofilament and an electrically conductive thread crocheted about the elastomeric monofilament.

In accordance with a preferred embodiment of the present invention the elastomeric monofilament is formed of polyurethane. Additionally or alternatively, the elastomeric monofilament has a thickness of between 40 and 1800 denier. More preferably, the elastomeric monofilament has a thickness of between 40 and 610 denier.

In accordance with a preferred embodiment of the present invention the electrically conductive thread is formed of silver-coated synthetic fiber. Alternatively, the electrically conductive thread is formed of nanocarbon-impregnated synthetic fiber. Preferably, the electrically conductive thread is formed of nanocarbon-impregnated synthetic fiber of thickness ranging from 70-3200 denier.

In accordance with a preferred embodiment of the present invention the electrically conductive thread is formed of a metal monofilament. Additionally, the electrically conductive thread is formed of a metal monofilament of a thickness exceeding 70 denier.

Preferably, the electrically conductive thread is crocheted around the elastomeric monofilament while the elastomeric monofilament is under tension.

There is also provided in accordance with another preferred embodiment of the present invention an electrically conductive fabric including electrically conductive yarn made into fabric by one of weaving, knitting and braiding, the electrically conductive yarn including an elastomeric monofilament and a conductive thread crocheted about the elastomeric monofilament.

Preferably, the fabric is a woven fabric having a warp and a woof and the warp is formed of the electrically conductive yarn. Alternatively, the fabric is a knitted fabric and the electrically conductive yarn is interlaid therewith. In a further alternative embodiment of the present invention the fabric is a braided fabric and the electrically conductive yarn is incorporated therein as an axial yarn.

In accordance with a preferred embodiment of the present invention the elastomeric monofilament is formed of polyurethane or rubber. Preferably, the elastomeric monofilament has a thickness of between 40 and 1800 denier. More preferably, the elastomeric monofilament has a thickness of between 40 and 610 denier.

Preferably, the electrically conductive thread is formed of silver-coated synthetic fiber. Alternatively, the electrically conductive thread is formed of nanocarbon-impregnated synthetic fiber. In a further alternative embodiment the electrically conductive thread is formed of a metal filament.

There is further provided in accordance with yet another preferred embodiment of the present invention a method of forming an electrically conductive fabric including providing an elastic monofilament, enclosing the elastic monofilament with a conductive thread by crocheting, thereby producing a conductive elastic yarn and forming an electrically conductive fabric from the conductive elastic yarn.

In accordance with a preferred embodiment of the present invention the electrically conductive thread is crocheted around the elastomeric monofilament while the elastomeric monofilament is under tension.

Preferably, the fabric is a woven fabric having a warp and a woof and the warp is formed of the electrically conductive yarn. Alternatively, the fabric is a knitted fabric and the electrically conductive yarn is interlaid therewith. In a further alternative embodiment, the fabric is a braided fabric and the electrically conductive yarn is incorporated therein as an axial yarn.

In accordance with a preferred embodiment of the present invention the elastomeric monofilament is formed of polyurethane or rubber.

Preferably, the elastomeric monofilament has a thickness of between 40 and 1800 denier.

In accordance with a preferred embodiment of the present invention the electrically conductive thread is formed of silver-coated synthetic fiber. Alternatively, the electrically conductive thread is formed of nanocarbon-impregnated synthetic fiber. In a further alternative embodiment the electrically conductive thread is formed of a metal monofilament.

There is even further provided in accordance with still another preferred embodiment of the present invention a crocheted shielded electrical conductor including an electrical conductor and an insulated electrical wire crocheted about the electrical conductor.

Preferably, the electrical conductor includes an electrically conductive yarn.

In accordance with a preferred embodiment of the present invention the insulated electrical wire includes a glass-coated microwire. Preferably, the insulated electrical wire has a diameter of 5-75 microns.

There is still further provided in accordance with another preferred embodiment of the present invention a method of forming a shielded electrical signal carrier including providing an electrically conductive wire suitable for carrying an electrical signal and enclosing the electrically conductive wire with a shielding thread by crocheting, thereby producing a shielded signal carrier.

In accordance with a preferred embodiment of the present invention the electrically conductive wire suitable for carrying an electrical signal includes an electrically conductive yarn.

In accordance with a preferred embodiment of the present invention the shielding thread includes a glass-coated microwire.

Preferably, the shielding thread has a diameter of 5-75 microns.

### BRIEF DESCRIPTION OF THE DRAWINGS

The present invention will be understood and appreciated more fully from the following detailed description which refers to the drawings in which:

FIGS. 1A, 1B and 1C are simplified illustrations of steps in the manufacture of an electrically conductive yarn by crocheting in accordance with a preferred embodiment of the present invention;

FIGS. 1D and 1E are simplified illustrations of an electrically conductive yarn constructed and operative in accordance with a preferred embodiment of the present invention in respective tensioned and non-tensioned operative orientations;

FIGS. 2A and 2B are simplified illustrations of part of a woven fabric constructed using a crocheted electrically conductive yarn in accordance with a preferred embodiment of the present invention, FIG. 2B being a simplified sectional illustration taken along lines B-B in FIG. 2A;

FIGS. 3A and 3B are simplified illustrations of part of a braided fabric constructed using a crocheted electrically conductive yarn in accordance with a preferred embodiment of the present invention, FIG. 3B being a simplified sectional illustration taken along lines B-B in FIG. 3A;

FIG. 4 is a simplified illustration of part of a knitted fabric constructed using a crocheted electrically conductive yarn in accordance with a preferred embodiment of the present invention; and

FIGS. 5A, 5B, 5C and 5D are simplified illustrations of steps in the manufacture of a shielded electrical conductor by crocheting in accordance with a preferred embodiment of the present invention.

### DETAILED DESCRIPTION OF A PREFERRED EMBODIMENT

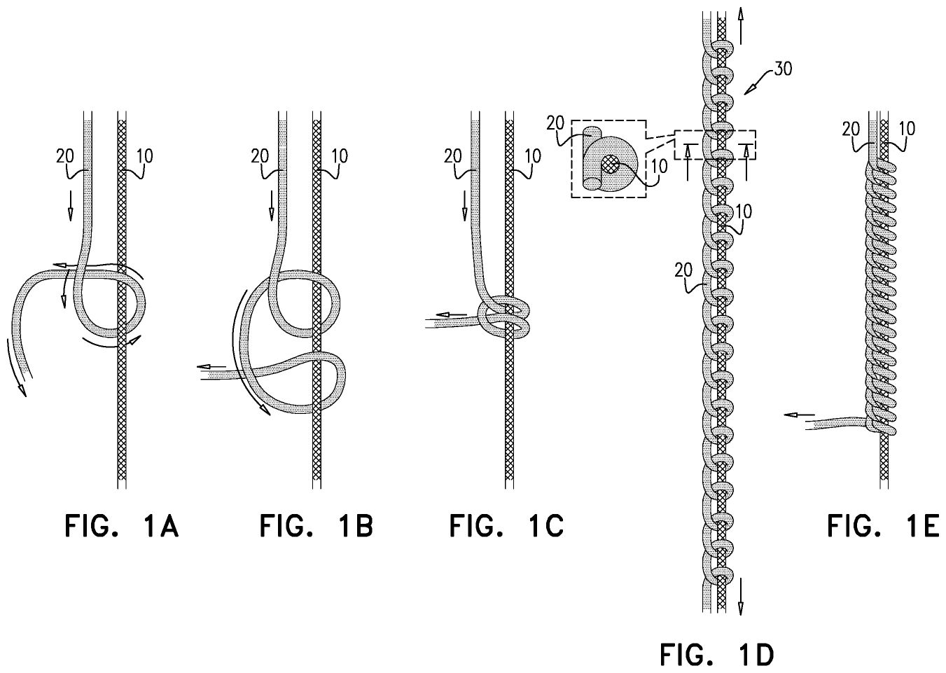

Reference is now made to FIGS. 1A-1C, which are simplified illustrations of steps in the manufacture of an electrically conductive yarn in accordance with a preferred embodiment of the present invention.

As seen in FIG. 1A, a conventional elastomeric monofilament 10 is preferably provided. Elastomeric monofilament 10 preferably is formed from polyurethane and has a thickness of between 40 and 1800 denier and more preferably between 40 and 610 denier. An example of a suitable elastomeric monofilament 10 is LYCRA®. An alternative example of a suitable elastomeric monofilament 10 is natural rubber thread.

An electrically conductive thread 20 is preferably provided. Electrically conductive thread 20 preferably is formed of silver-coated synthetic fiber, such as nylon, or of nanocarbon-impregnated synthetic fiber having a thickness of between 70 denier and 3200 denier or of a metal monofilament of thickness 2350 denier. An example of a suitable electrically conductive thread 20 formed of silver-coated synthetic fiber is commercially available from Statex of Bremen, Germany under part number 200121011025. An example of a suitable electrically conductive thread 20 formed of nanocarbon-impregnated synthetic fiber is commercially available from Dexmat of Houston, Texas under part identifier carbon nanotube yarn. An example of a suitable electrically conductive thread 20 formed of a metal monofilament is commercially available from Bekaert of Belgium under catalog number 9006070.

As seen in FIGS. 1A-1C, the electrically conductive thread 20 is crocheted around the elastomeric monofilament 10, while the elastomeric monofilament 10 is under tension. The resulting crocheted electrically conductive yarn 30 is seen in FIG. 1D and 1E under tension and at rest, respectively.

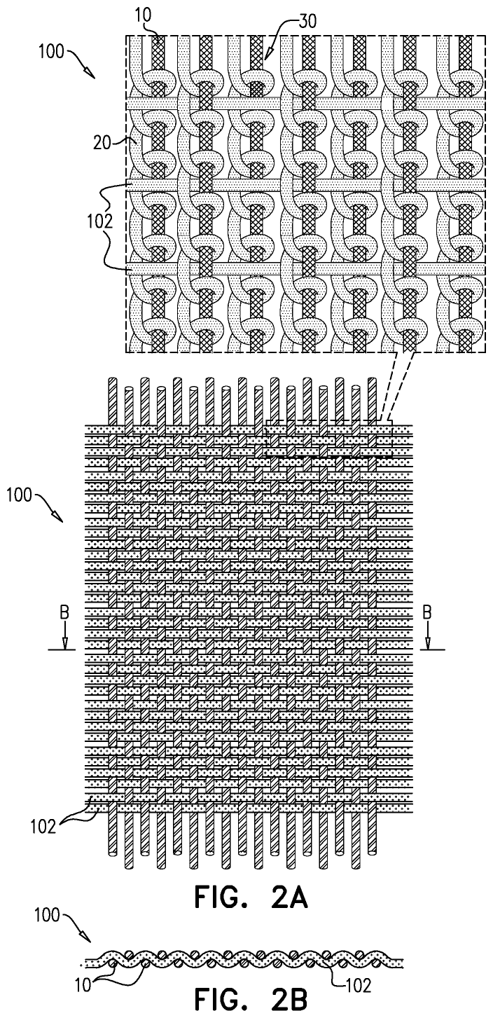

Reference is now made to FIGS. 2A and 2B, which are simplified illustrations of part of a woven fabric 100, constructed using a crocheted electrically conductive yarn 30, in accordance with a preferred embodiment of the present invention. As seen in FIGS. 2A and 2B, the woven fabric 100 may be woven in a conventional manner using conventional weaving machines. It is seen that the warp of the woven fabric 100 comprises crocheted electrically conductive yarn 30. The woof, indicated by reference numeral 102, may be any suitable yarn and need not be conductive or elastomeric.

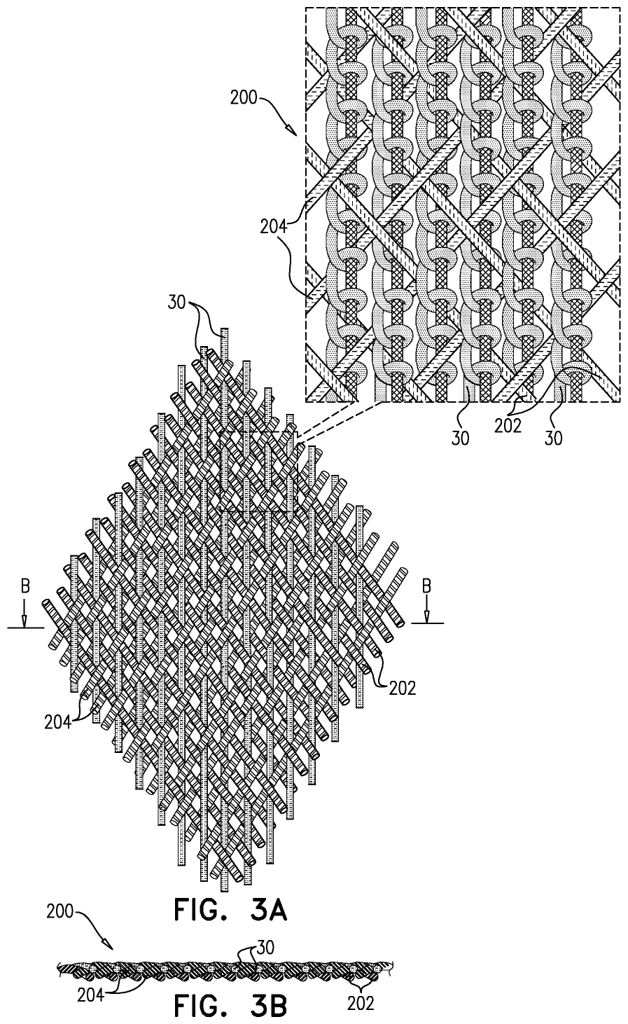

Reference is now made to FIGS. 3A and 3B, which are simplified illustrations of part of a braided fabric 200, constructed using a crocheted electrically conductive yarn, in accordance with a preferred embodiment of the present invention. As seen in FIGS. 3A and 3B, the braided fabric 200 may be braided in a conventional manner using conventional braiding machines. It is seen that the axial yarn of the braided fabric 200 comprises crocheted electrically conductive yarn 30. The mutually orthogonal braided yarns, indicated by reference numerals 202 and 204, may each be any suitable yarn and need not be conductive or elastomeric.

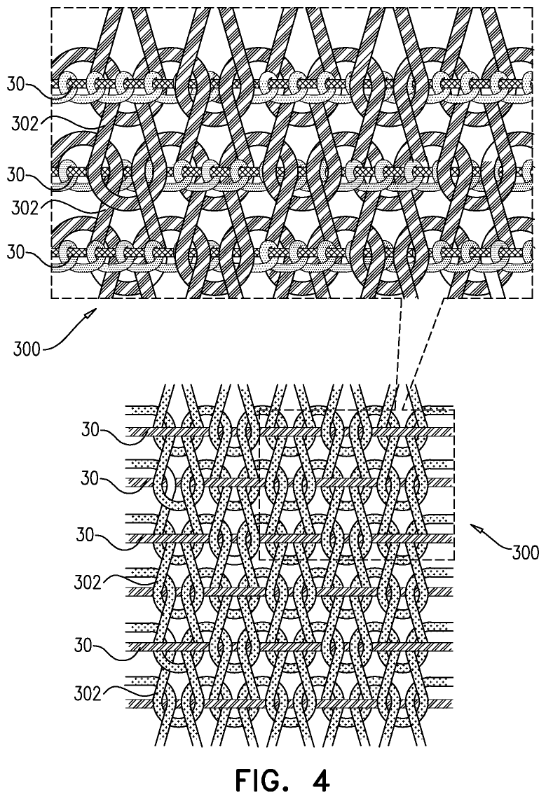

Reference is now made to FIG. 4, which is a simplified illustration of part of a knitted fabric 300, constructed using a crocheted electrically conductive yarn in accordance with a preferred embodiment of the present invention. As seen in FIG. 4, the knitted fabric 300 may be knitted in a conventional manner using conventional knitting machines. It is seen that the crocheted electrically conductive yarn 30 is interlaid with the knitted course, indicated by reference numeral 302. The knitted loops 302 may be any suitable yarn and need not be conductive or elastomeric.

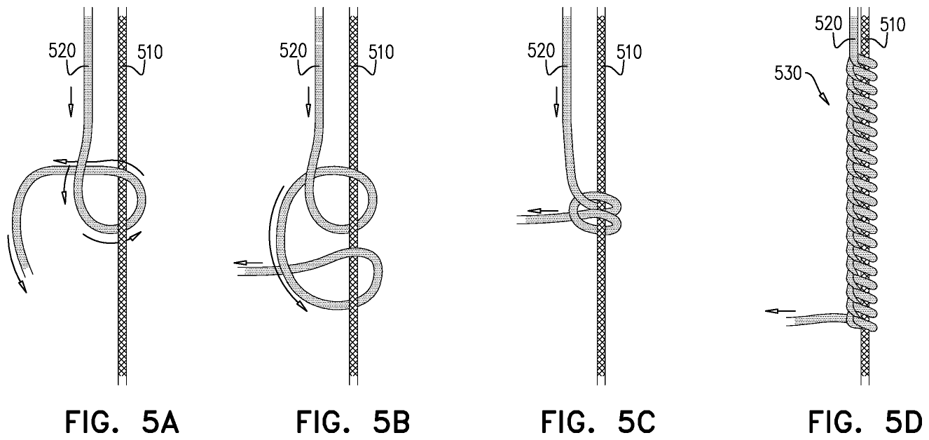

Reference is now made to FIGS. 5A-5D, which are simplified illustrations of steps in the manufacture of a shielded electrical conductor suitable for use as a signal carrier in accordance with a preferred embodiment of the present invention.

As seen in FIG. 5A, an electrical conductor 510 is provided. Electrical conductor 510 may be formed of copper or any other suitable electrical conductor and could be an electrically conductive yarn as described hereinabove with reference to FIGS. 1A-1E.

An insulated electrically conductive wire 520 is preferably provided. Electrically conductive wire 520 is preferably a glass-coated microwire, commercially available from Wire Metal Technologies Ltd. of Or Akiva Israel, and has a diameter of 5-75 microns and is formed of, for example, copper, cobalt or silver.

As seen in FIGS. 5A-5D, the electrically conductive wire 520 is crocheted around the electrical conductor 510. The resulting crocheted shielded electrical conductor 530 is seen in FIG. 5D. It is appreciated that fabrics of the type shown in FIGS. 2A-4 may be manufactured from the crocheted shielded electrical conductor 530 generally in the manner described hereinabove with reference to FIGS. 2A 4.

It will be appreciated by persons skilled in the art that the present invention is not limited by what has been particularly shown and described hereinabove. Rather the invention includes both combinations and subcombinations of features described herein as well as modifications thereof which are not in the prior art.

1. An electrically conductive yarn comprising:
an elastomeric monfilament; and
an electrically conductive thread crocheted about said elastomeric monofilament.

2. An electrically conductive yarn according to claim 1 and wherein said elastomeric monofilament is formed of polyurethane.

3. An electrically conductive yarn according to claim 1 and wherein said elastomeric monofilament has a thickness of between 40 and 1800 denier.

4. An electrically conductive yarn according to claim 1 and wherein said elastomeric monofilament has a thickness of between 40 and 610 denier.

5. An electrically conductive yarn according to claim 1 and wherein said electrically conductive thread is formed of silver-coated synthetic fiber.

6. An electrically conductive yarn according to claim 1 and wherein said electrically conductive thread is formed of nanocarbon-impregnated synthetic fiber.

7. An electrically conductive yarn according to claim 6 and wherein said electrically conductive thread is formed of nanocarbon-impregnated synthetic fiber of thickness ranging from 70-3200 denier.

8. An electrically conductive yarn according to claim 1 and wherein said electrically conductive thread is formed of a metal monofilament.

9. An electrically conductive yarn according to claim 8 and wherein said electrically conductive thread is formed of a metal monofilament of a thickness exceeding 70 denier.

10. An electrically conductive yarn according to claim 1 and wherein said electrically conductive thread is crocheted around said elastomeric monofilament while said elastomeric monofilament is under tension.

11. An electrically conductive fabric comprising:
electrically conductive yarn made into fabric by one of weaving, knitting and braiding, said electrically conductive yarn comprising:
an elastomeric monofilament; and
a conductive thread crocheted about said elastomeric monofilament.

12. An electrically conductive fabric according to claim 11 and wherein:
said fabric is a woven fabric having a warp and a woof; and
the warp is formed of said electrically conductive yarn.

13. An electrically conductive fabric according to claim 11 and wherein:
said fabric is a knitted fabric; and
said electrically conductive yarn is interlaid therewith.

14. An electrically conductive fabric according to claim 11 and wherein:
said fabric is a braided fabric; and
said electrically conductive yarn is incorporated therein as an axial yarn.

15. An electrically conductive fabric according to claim 11 and wherein said elastomeric monofilament is formed of polyurethane or rubber.

16. An electrically conductive fabric according to 15 and wherein said elastomeric monofilament has a thickness of between 40 and 1800 denier.

17. An electrically conductive fabric according to claim 16 and wherein said elastomeric monofilament has a thickness of between 40 and 610 denier.

18. An electrically conductive fabric according to claim 11 and wherein said electrically conductive thread is formed of silver-coated synthetic fiber.

19. An electrically conductive fabric according to claim 11 and wherein said electrically conductive thread is formed of nanocarbon-impregnated synthetic fiber.

20. An electrically conductive fabric according to claim 11 and wherein said electrically conductive thread is formed of a metal filament.

21. A method of forming an electrically conductive fabric comprising:
providing an elastic thread,
enclosing said elastic monofilament with a conductive thread by crocheting, thereby producing a conductive elastic yarn; and
forming an electrically conductive fabric from said conductive elastic yarn.

22. A method of forming an electrically conductive fabric according to claim 21 and wherein said electrically conductive thread is crocheted around said elastomeric monofilament while said elastomeric monofilament is under tension.

23. A method of forming an electrically conductive fabric according to claim 21 and wherein:
said fabric is a woven fabric having a warp and a woof; and
the warp is formed of said electrically conductive yarn.

24. A method of forming an electrically conductive fabric according to claim 21 and wherein:
said fabric is a knitted fabric; and
said electrically conductive yarn is interlaid therewith.

25. A method of forming an electrically conductive fabric according to claim 21 and wherein:
said fabric is a braided fabric; and
said electrically conductive yarn is incorporated therein as an axial yarn.

26. A method of forming an electrically conductive fabric according to claim 21 and wherein said elastomeric monofilament is formed of polyurethane or rubber.

27. A method of forming an electrically conductive fabric according to claim 21 and wherein said elastomeric monofilament has a thickness of between 40 and 1800 denier.

28. A method of forming an electrically conductive fabric according to claim 21 and wherein said electrically conductive thread is formed of silver-coated synthetic fiber.

29. A method of forming an electrically conductive fabric according to claim 21 and wherein said electrically conductive thread is formed of nanocarbon-impregnated synthetic fiber.

30. A method of forming an electrically conductive fabric according to claim 21 and wherein said electrically conductive thread is formed of a metal monofilament.

31. A crocheted shielded electrical conductor comprising:
an electrical conductor; and
an insulated electrical wire crocheted about said electrical conductor.

32. A crocheted shielded electrical conductor according to claim 31 and wherein said electrical conductor comprises an electrically conductive yarn according to claim 1.

33. A crocheted shielded electrical conductor according to claim 31 and wherein said insulated electrical wire comprises a glass-coated microwire.

34. A crocheted shielded electrical conductor according to claim 31 and wherein said insulated electrical wire has a diameter of 5-75 microns.

35. A method of forming a shielded electrical signal carrier comprising:
providing an electrically conductive wire suitable for carrying an electrical signal, and
enclosing said electrically conductive wire with a shielding thread by crocheting, thereby producing a shielded signal carrier.

36. A method of forming a shielded electrical signal carrier according to claim 35 and wherein said electrically conductive wire suitable for carrying an electrical signal comprises an electrically conductive yarn according to claim 1.

37. A method of forming a shielded electrical signal carrier according to claim 35 and wherein said shielding thread comprises a glass-coated microwire.

38. A method of forming a shielded electrical signal carrier according to claim 35 and wherein said shielding thread has a diameter of 5-75 microns.
